(19) United States
(12) Patent Application Publication
(10) Pub. No.: US 2012/0100669 A1
(43) Pub. Date: Apr. 26, 2012

(54) METHOD OF MANUFACTURING TMV PACKAGE-ON-PACKAGE DEVICE

(75) Inventors: Se Young JANG, Seongnam-si (KR); Kun Tak KIM, Suwon-si (KR); Jeong Ung KIM, Suwon-si (KR)

(73) Assignee: SAMSUNG ELECTRONICS CO. LTD., Suwon-si (KR)

(21) Appl. No.: 13/279,655

(22) Filed: Oct. 24, 2011

(30) Foreign Application Priority Data
Oct. 25, 2010 (KR) 10-2010-0103834

(51) Int. Cl. H01L 21/60

(52) U.S. Cl. 438/107; 257/E21.509

(57) ABSTRACT

A method of manufacturing a Through Mold Via (TMV) package-on-package device while preventing a bad solder joint from occurring in the TMV package-on-package device is provided. The method includes coating exposed portions of a lower semiconductor package with an organic soldering preservative, and stacking a top semiconductor package on the lower semiconductor package and connecting lower solder balls of the top semiconductor package with the top solder balls of the lower semiconductor package. According to the method, a bad solder joint may be prevented from occurring when a top semiconductor package is bonded to a lower semiconductor package.

### PRIORITY

This application claims the benefit under 35 U.S.C. §119(a) of a Korean patent application filed on Oct. 25, 2010 in the Korean Intellectual Property Office and assigned Serial No. 10-2010-0103834, the entire disclosure of which is hereby incorporated by reference.

### BACKGROUND OF THE INVENTION

1. Field of the Invention

The present invention relates to a method of manufacturing a Through Mold Via (TMV) package-on-package device. More particularly, the present invention relates to a method of manufacturing a TMV package-on-package device while preventing a bad solder joint from occurring in the TMV package-on-package device.

2. Description of the Related Art

Recently, System In Package (SIP) technology is widely employed because of a trend toward multifunction, high capacity, and small semiconductor packages. SIP technology is used to integrate several existing packages into a new package while reducing the size of an electronic device. SIP technology is implemented by multi-chip package technology of stacking several semiconductor chips and by package-on-package technology of stacking several semiconductor chips vertically. However, since it is difficult to implement multifunction and high capacity semiconductor packages only with the multi-chip package technology, the package-on-package technology is frequently utilized.

FIGS. 1A through 1C are sectional views illustrating a method of manufacturing a normal package-on-package device according to the related art.

Referring to FIG. 1A, a lower semiconductor package 110, in which molding materials 113 for molding a semiconductor chip 112 and a top pad 114 are formed on the upper side of a lower semiconductor package substrate 111, is manufactured.

Referring to FIG. 1B, a top semiconductor package 120, in which a plurality of semiconductor chips 122 are stacked on a top semiconductor package substrate 121 and in which lower solder balls 124 are formed on the lower side of the top semiconductor package substrate 122, is manufactured.

Referring to FIG. 1C, the top semiconductor package 120 is stacked on the lower semiconductor package and the lower solder balls 124 of the top semiconductor package 120 are bonded to the top pad 114 of the lower semiconductor package 110.

The normal package-on-package device 100 manufactured by the above-mentioned method does not oxidize and has excellent wetness because the top pad 114 coated with gold (Au). However, in the normal package-on-package device 100, warpage is generated because of different components of the lower solder balls 124 and the top pad 114 to be bonded to each other and there is a limit to increasing the number of pins used to electrically connect the top semiconductor package 120 to the lower semiconductor package 110. In order to address the problem, Through Mold Via (TMV) package-on-package technology is developed.

FIGS. 2A through 2C illustrate a method of manufacturing a TMV package-on-package device according to the related art.

Referring to FIG. 2A, a lower semiconductor package 210, in which molding materials 213 for molding a semiconductor chip 212 are formed on a lower semiconductor package substrate 211 and in which top solder balls 214 are formed between the molding materials 213, is manufactured.

Referring to FIG. 2B, a top semiconductor package 220, on which a plurality of semiconductor chips 222 are stacked on a top semiconductor package substrate 221 and in which lower solder balls 224 are formed on the lower side of a top semiconductor package substrate 222, is manufactured.

Referring to FIG. 2C, the top semiconductor package 220 is stacked on the lower semiconductor package 210 and the lower solder balls 224 of the top semiconductor package 220 are bonded to the top solder balls 214 of the lower semiconductor package 210.

The TMV package-on-package device 200 may be prevented from being twisted because the lower solder balls 224 and the top solder balls 214 that form TMV 230 have the same components, and the number of pins electrically connecting the top semiconductor package 220 to the lower semiconductor package 210 may be increased by more than that of the normal package-on-package device. However, since the top solder balls 214 of the lower semiconductor package 210 is made of uncoated tin, oxide layers are formed on exposed portions of the top solder balls 214 before bonding between the lower solder balls 224 of the top semiconductor package 220 and the top solder balls 214 of the lower semiconductor package 210 and due to this wetness becomes inferior, resulting in occurring bad solder joints between the top semiconductor package and the lower semiconductor package.

Therefore, a need exists for a method of manufacturing a TMV package-on-package device while preventing a bad solder joint from occurring when connecting a top semiconductor package to a lower semiconductor package in the TMV package-on-package device.

### SUMMARY OF THE INVENTION

Aspects of the present invention are to address at least the above-mentioned problems and/or disadvantages and to provide at least the advantages describe below. Accordingly, an aspect of the present invention is to provide a method of manufacturing a Through Mold Via (TMV) package-on-package device while preventing a bad solder joint from occurring when connecting a top semiconductor package to a lower semiconductor package in the TMV package-on-package device.

In accordance with an aspect of the present invention, a method of manufacturing a TMV package-on-package device is provided. The method includes coating exposed portions of a lower semiconductor package with an organic soldering preservative, and stacking a top semiconductor package on the lower semiconductor package and connecting lower solder balls of the top semiconductor package with the top solder balls of the lower semiconductor package.

According to the method of the present invention, an organic soldering preservative is coated on the exposed portions of the top solder balls of the lower semiconductor package to prevent a bad solder joint from occurring when connecting the top semiconductor package to the lower semiconductor package. Therefore, productivity of surface-mount devices may be improved.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of the present invention will be more apparent from the following description taken in conjunction with the accompanying drawings, in which:

FIGS. 1A through 1C are sectional views illustrating a method of manufacturing a normal package-on-package device according to the related art;

FIGS. 2A through 2C are sectional views illustrating a method of manufacturing a Through Mold Via (TMV) package-on-package device according to the related art;

FIG. 3 is a flowchart illustrating a method of manufacturing a TMV package-on-package device according to an exemplary embodiment of the present invention; and

FIGS. 4A through 4G are sectional views illustrating a method of manufacturing a lower semiconductor package according to exemplary embodiments of the present invention.

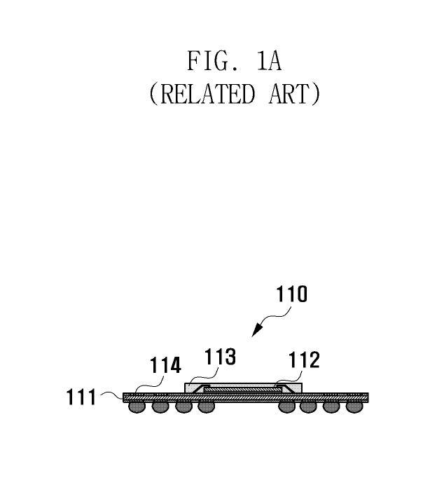

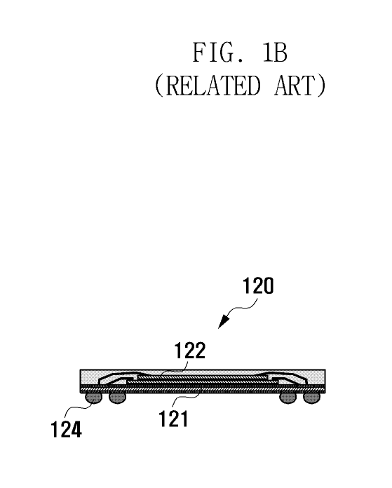

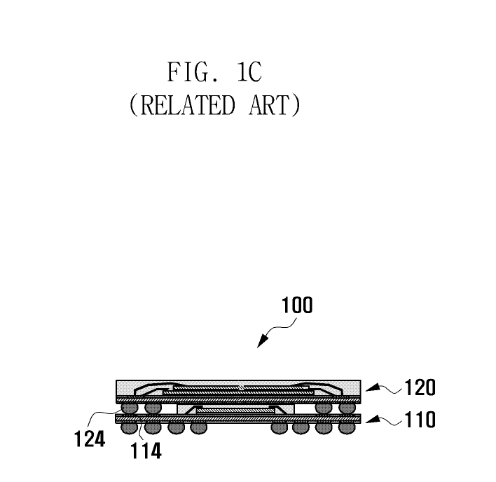

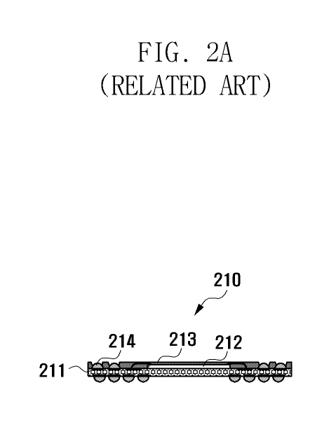

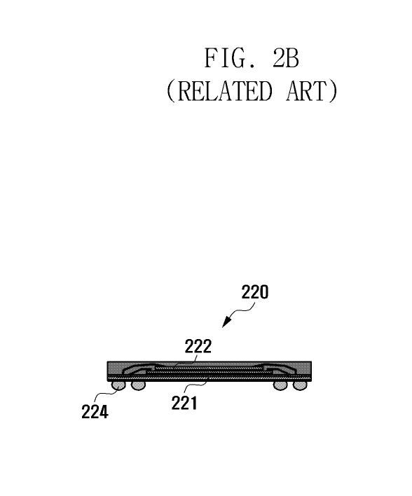

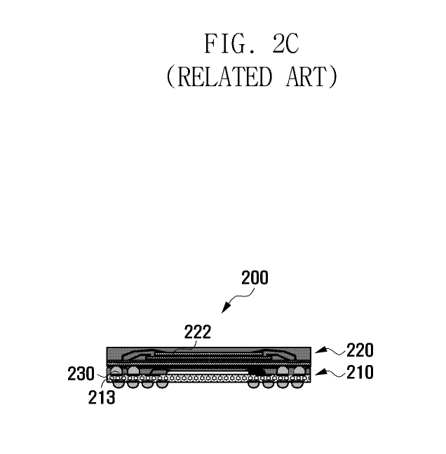

Throughout the drawings, it should be noted that like reference numbers are used to depict the same or similar elements, features, and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to skill in the art, may occur in amounts that do not preclude the effect the characteristic was intended to provide.

Exemplary embodiments of the present invention provide a method of manufacturing a Through Mold Via (TMV) package-on-package device while preventing the occurrence of a bad solder joint when connecting a top semiconductor package to a lower semiconductor package in a TMV package-on-package device.

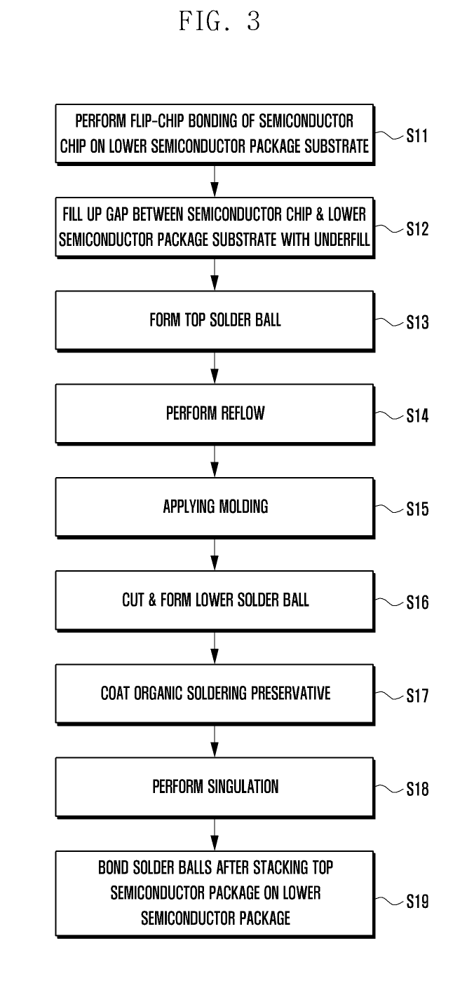

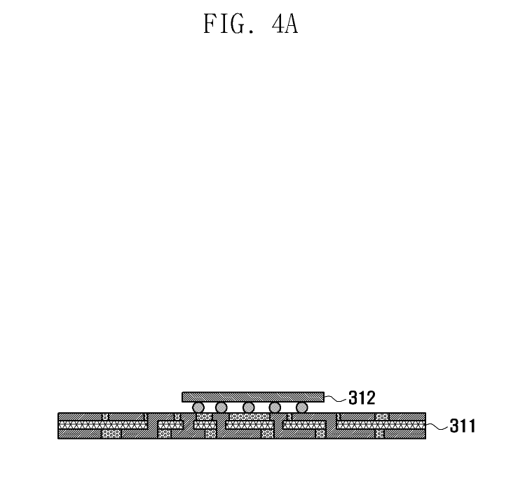

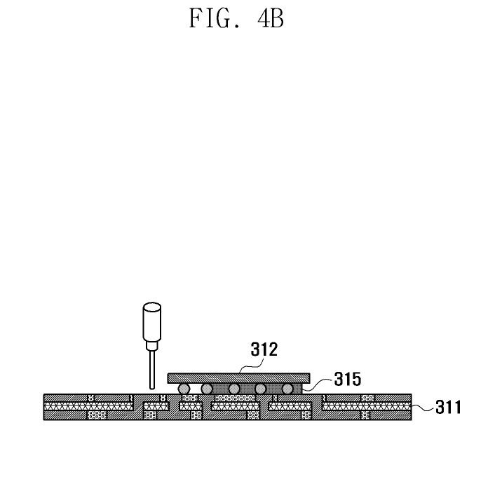

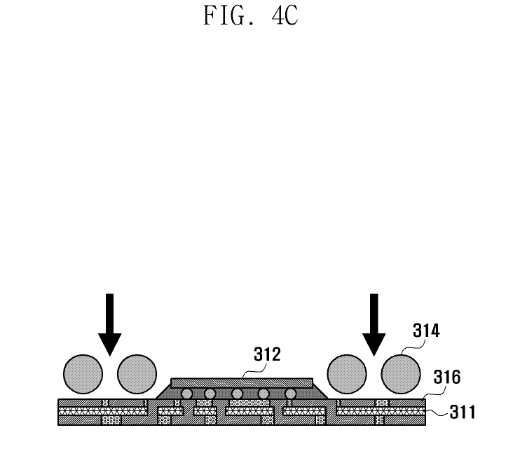

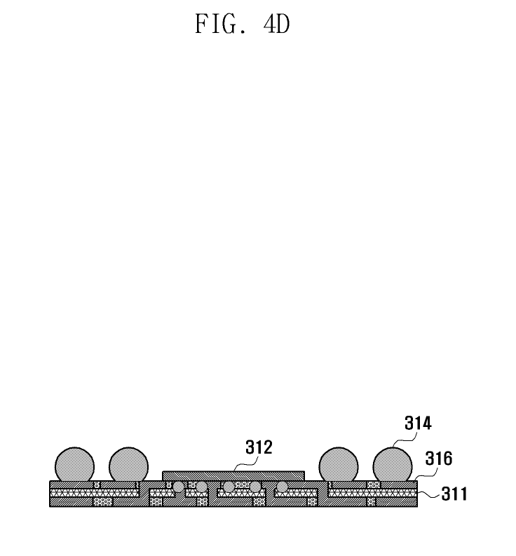

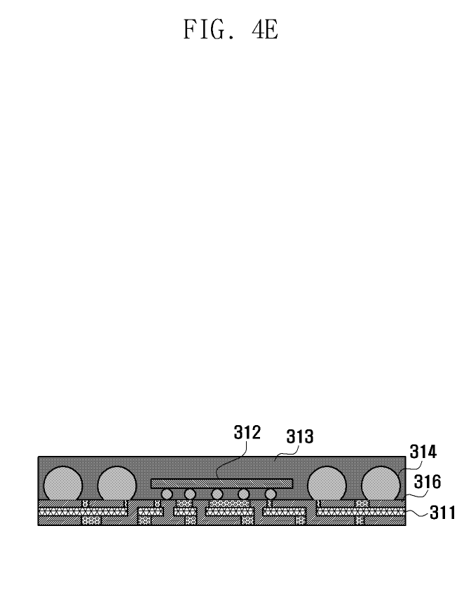

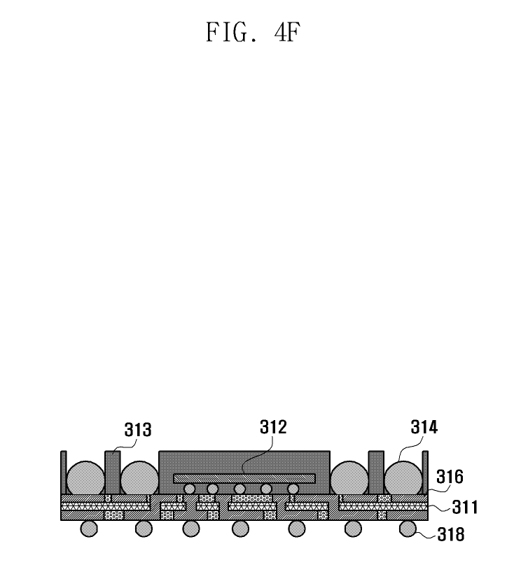

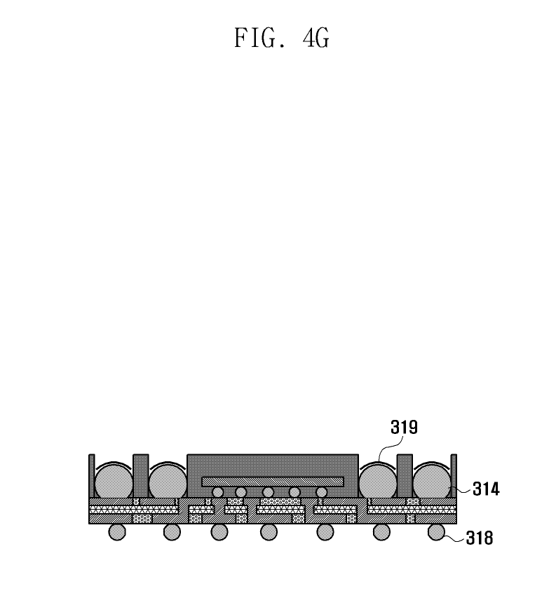

FIGS. 3 through 4G, discussed below, and the various exemplary embodiments used to describe the principles of the present disclosure in this patent document are by way of illustration only and should not be construed in any way that would limit the scope of the disclosure. Those skilled in the art will understand that the principles of the present disclosure may be implemented in any suitably arranged communications system. The terms used to describe various embodiments are exemplary. It should be understood that these are provided to merely aid the understanding of the description, and that their use and definitions in no way limit the scope of the invention. Terms first, second, and the like are used to differentiate between objects having the same terminology and are in no way intended to represent a chronological order, unless where explicitly state otherwise. A set is defined as a non-empty set including at least one element.

FIG. 3 is a flowchart illustrating a method of manufacturing a TMV package-on-package device according to an exemplary embodiment of the present invention. FIGS. 4A through 4G are sectional view illustrating a method of manufacturing a lower semiconductor package according to exemplary embodiments of the present invention.

Referring to FIGS. 3 through 4G, a flip-chip bonding for manufacturing of a lower semiconductor package is performed in step S11. In the flip-chip bonding of step S11, a semiconductor chip 312 is flip-chip bonded on a stripped lower semiconductor package substrate 311, as illustrated in FIG. 4A. The semiconductor chip 312 mounted on the lower semiconductor package substrate 311 may be an application processor or a central processor. In step S12, an underfilling is performed to fill in a gap between the semiconductor chip 312 and the lower semiconductor package substrate 311 with an underfill 315, as illustrated in FIG. 4B.

In step S13, a top solder ball forming is performed and top solder balls 314 are formed on a top pad 316 of a lower semiconductor package substrate, as illustrated in FIG. 4C. In step S14, a reflowing is performed such that reflow soldering is performed to bond the top solder balls 314 to the top pad 316, as illustrated in FIG. 4D. In step S15, a molding is performed such that the semiconductor chip 312 and the top solder balls 314 are molded with molding material 313, as illustrated in FIG. 4E. In step S16, cutting is performed to cut off the molding material 313 such that tops of the top solder balls 314 and to bond lower solder balls 318 to the lower side of the lower semiconductor package substrate 311, as illustrated in FIG. 4F. The cutting may be performed by laser cutting.

In step S17, organic soldering preservative coating is performed to coat organic soldering preservative 319 to the exposed portions of the top solder balls 314, as illustrated in FIG. 4G. The organic soldering preservative coating may be performed by strip dipping in which a strip is dipped into organic soldering preservative solution, by a nozzle coating in which the coating is performed with a nozzle, or by spray coating using a spray. When the strip dipping is employed, even the lower solder balls 318 may be easily coated with the organic soldering preservative. In step S18, simulation is performed to cut a strip into respective lower semiconductor packages. Although the organic soldering preservative is coated in a strip state before performing the singulation in the exemplary embodiment of the present invention, the coating of the organic soldering preservative may be performed after the singulation.

In step S19, bonding of solder ball is performed such that the top semiconductor package is stacked on the lower semiconductor package and that the top solder balls of the lower semiconductor package are bonded to the lower solder balls of the top semiconductor package.

According to exemplary embodiments of the present invention, the top solder balls of the lower semiconductor package are bonded to the lower solder balls of the top semiconductor package, after manufacturing the lower semiconductor package in which the exposed portions of the top solder balls are coated with an organic soldering preservative. Thus, since an oxide layer is prevented from occurring on the exposed portions of the top solder balls of the lower semiconductor package, a bad solder joint may be prevented from occurring when the top solder balls of the lower semiconductor package are connected with the lower solder balls of the top solder balls. Therefore, productivity of Surface-Mount Device (SMD) may be improved.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. A method of manufacturing a Through Mold Via (TMV) package-on-package device, the method comprising:
coating exposed portions of a lower semiconductor package with an organic soldering preservative; and
stacking a top semiconductor package on the lower semiconductor package and connecting lower solder balls of the top semiconductor package with the top solder balls of the lower semiconductor package.

2. The method of claim 1, wherein the coating of the exposed portions of the lower semiconductor package is performed by strip dipping of dipping strips into an organic soldering preservative solution.

3. The method of claim 1, wherein the coating of the exposed portions of the lower semiconductor package is performed by nozzle coating with a nozzle.

4. The method of claim 1, wherein the coating of the exposed portions of the lower semiconductor package is performed by spray coating with a spray.

5. The method of claim 1, further comprising cutting a strip into respective lower semiconductor packages, performed after the coating of the exposed portions of the lower semiconductor package.

6. The method of claim 1, further comprising cutting a molding material for exposing tops of the top solder balls of the lower semiconductor package.

7. The method of claim 6, wherein the cutting of the molding material comprises bonding the lower solder balls to the lower side of a lower semiconductor package substrate.
